(19) United States
(12) Patent Application Publication
(10) Pub. No.: US 2024/0413570 A1
(43) Pub. Date: Dec. 12, 2024

(54) CONTACT-MAKING ARRANGEMENT, ELECTRONICS ASSEMBLY AND METHOD FOR ASSEMBLING AN ELECTRONICS ASSEMBLY

(71) Applicant: Robert Bosch GmbH, Stuttgart (DE)

(72) Inventors: Andreas Otto, Hoerselberg-Hainich (DE); Andreas Meier, Pfullingen (DE); Rene Kloetzig, Reutlingen (DE)

(21) Appl. No.: 18/702,040

(22) PCT Filed: Oct. 10, 2022
(86) PCT No.: PCT/EP2022/078107

§ 371 Date: Apr. 17, 2024

(30) Foreign Application Priority Data
Nov. 26, 2021 (DE) 10 2021 213 350.9

(51) Int. Cl. H01R 13/58; H01R 12/57; H01R 12/71

(52) U.S. Cl. CPC H01R 13/5804; H01R 12/57; H01R 12/718

(57) ABSTRACT

The present invention relates to a contact-making arrangement (1) for electrically conductive connection between a clamping connector (2) and a joining partner (3), comprising a printed circuit board (4) with a cutout (8), wherein an x-axis (5) and a y-axis (6) perpendicular thereto are defined in the plane of the printed circuit board (4), a joining partner (3) and a clamping connector (2) which is arranged on the cutout (8) and has at least one flexible contact element (11), wherein the joining partner (3) can be inserted through the clamping connector (2) and into the cutout (8) with simultaneous contact-connection and deformation of the contact element (11), wherein the inserted joining partner (3) can be moved parallel to the y-axis (6) in a manner sliding on the at least one contact element (11).

### BACKGROUND

The present invention relates to a contact-making arrangement for electrically conductive connection between a clamping connector and a joining partner. Furthermore, the invention relates to an electronic assembly, in particular with a power component, in which the contact-making arrangement is used. In addition, the invention shows a method for assembling the electronic assembly.

From the prior art, contact-making arrangements are known in which a corresponding joining partner is thermally connected to a connecting element on a printed circuit board, in particular by soldering or welding. In addition, so-called cold contact-connection techniques are known, in which a frictional and interlocking connection between the contacts is made, for example by pressing or clamping. In the case of thermal contact-connection, the elements to be soldered or welded must be accessible during assembly, for which corresponding installation space must be reserved in the electronic assembly. The cold contact-connection technique requires a relatively accurate positioning of the joining partner relative to the corresponding counterpart, which makes the assembly process correspondingly complex.

### SUMMARY

Compared to the prior art, the contact-making arrangement according to the invention has the advantage that the contact-connection between a clamping connector and an associated joining partner is made by simply inserting the elements into one another; no accessibility is required for any weld or soldering connection. In addition, the contact-making arrangement presented herein allows for very large production-related or concept-related tolerances with regard to the relative positioning of the clamping connector and joining partner. For the contact-making arrangement presented herein, correspondingly large contact areas or line cross-sections are possible, so it can easily be used in the field of power electronics. No complex tools are needed to make the electrically conductive connection. In addition, the contact is made directly on the printed circuit board (circuit carrier). This results in a very space-saving design. These advantages are achieved by the following contact-making arrangement for the electrically conductive connection between a clamping connector and a joining partner. The contacting assembly includes a printed circuit board with a cutout. An x-axis and a y-axis perpendicular thereto are defined in the plane of the printed circuit board. A z-axis extends perpendicular to the x-axis and y-axis. A joining partner is inserted parallel to this z-axis. Furthermore, the contact-making arrangement comprises a clamping connector. This clamping connector is arranged on the cutout of the printed circuit board. In particular, the clamping connector is connected to the printed circuit board and contact-connected on the printed circuit board. The clamping connector extends in particular across this cutout and can be arranged on the bottom or top of the printed circuit board. In particular, in the middle of the clamping connector, there is a hole that is aligned with the cutout in the printed circuit board. The hole in the clamping connector is in particular a through-hole. The cutout in the printed circuit board can be, for example, a pocket or a through-hole. The clamping connector comprises at least one flexible contact element which is configured so that the joining partner can be inserted through the clamping connector with simultaneous contact-connection and deformation of the contact element. When inserting the joining partner, the joining partner also projects into the cutout of the printed circuit board. In principle, it is irrelevant whether the joining partner is first inserted through the clamping connector and then into the cutout, or first guided through the cutout and then enters the clamping connector. The inserted joining partner can be moved parallel to the y-axis relative to the clamping connector and relative to the printed circuit board. In so doing, the joining partner slides on the at least one contact element, preferably on all the contact elements present. Accordingly, it is in particular provided that the contact elements do not surround the joining partner all away around, for example, as would be the case with a pin-shaped joining partner with a round cross-section. Rather, the contact elements are arranged and the joining partner is configured in such a way that the joining partner can be moved parallel to the y-axis and simultaneously the contact element or the plurality of contact elements slide on the joining partner. This results in a correspondingly high tolerance in the y-direction with regard to the relative positioning of the joining partner and clamping connector.

Preferably, the clamping connector comprises a plurality of flexible contact elements. Preferably, 2 to 10 flexible contact elements are provided. The joining partner is particularly preferably configured as a contact blade. The contact blade is characterized in particular by the joining partner having a length and a width in its cross section (in the x-y plane), wherein the length is substantially greater than the width. In particular, the length is at least three times as large as the width. The length of the contact blade is defined parallel to the y-axis. Accordingly, the width of the contact blade extends parallel to the x-axis.

The joining partner preferably comprises two opposing contact surfaces. In particular, each contact surface is perpendicular to the x-axis. It is preferably provided that the joining partner is only contact-connected at these two contact surfaces. In particular, the clamping connector has at least two opposing flexible contact elements for this purpose. As a result, at least one of the flexible contact elements abuts each contact surface of the joining partner.

In addition to the two opposing contact surfaces, the joining partner preferably comprises two opposing flank surfaces. The contact surfaces preferably extend over the entire length of the contact blade in the x-y plane. Accordingly, the flank surfaces in the same plane preferably extend across the relatively narrow width of the joining partner. It is preferably provided that no contact-connection is made on these flank surfaces, in particular that none of the contact elements abut. This results in a very free movement of the joining partner parallel to the y-axis with simultaneous sliding of the contact elements on the two contact surfaces.

The joining partner can preferably be moved parallel to the x-axis with simultaneous deformation of the at least one contact element.

Preferably, the contact-making arrangement is configured such that the joining partner can be moved relative to the clamping connector parallel to the y-axis by at least 1 mm, preferably at least 2 mm, more preferably at least 3 mm. Additionally or alternatively, it is preferably provided that the contact-making arrangement is configured such that the joining partner is movable relative to the clamping connector parallel to the x-axis by at least 1 mm, preferably at least 2 mm, more preferably at least 3 mm. This is achieved in particular by the correspondingly large design of the cutout in the printed circuit board or the hole in the clamping connector.

The movability of the joining partner relative to the clamping connector parallel to the z-axis results from the correspondingly large design of the joining partner in this direction and because the elastic contact elements slide on the contact surfaces and are not fixedly connected to the contact surfaces.

The clamping connector is preferably formed by a sheet metal. In particular, it is a punched plate. Particularly preferably, the clamping connector is a one-piece component. Particularly preferably, the clamping connector lies flat on the printed circuit board. The sheet metal from which the clamping connector is formed thus extends substantially in the x-y plane. However, the contact elements may be pre-curved in a direction parallel to the z-axis.

Particularly preferably, the at least one contact element, preferably all of the contact elements used, comprise a notch. The desired flexibility of the contact element or its spring force can be adjusted by means of this notch.

As described, the clamping connector comprises a hole into which the joining partner is inserted. This hole is preferably surrounded by a frame that is integrally manufactured with the at least one contact element, preferably with all the contact elements used. From the frame, the at least one contact element, preferably all the contact elements used, extend parallel to the x-axis into the hole and/or across the hole.

The clamping connector is preferably attached to the printed circuit board as a surface-mounted device (SMD) and is thus contact-connected. Here, SMD describes a surface-mounted device or surface-mounted component. Preferably, the clamping connector is contact-connected with the printed circuit board along its entire circumference, i.e., fully circumferential and thus closed in an annular fashion. This fully-circumferential contact-connection, and in particular the symmetrical design of the circumference of the clamping connector, prevent interfering influences when used in power electronics or at corresponding frequencies.

The invention further comprises an electronic assembly. The electronic assembly comprises a housing and at least one electrical or electronic component. The component is in particular a power component of a power electronics circuit. The component is arranged in the housing, in particular attached in the housing. Furthermore, the electronic assembly comprises one of the contact-making arrangements described. The joining partner is electrically conductively connected to the component. In particular, the joining partner projects out of the component. The printed circuit board is inserted into the housing and the joining partner is inserted into the clamping connector. Of course, a plurality of joining partners and a plurality of the clamping connectors can be used in the electronic assembly.

The advantageous configurations and associated dependent-claims described in the context of the contact-making arrangement according to the invention find corresponding advantageous application in the electronic assembly according to the invention.

In the electronic assembly, the component is contact-connected by simply inserting the printed circuit board. Since the contact-making arrangement presented here allows a relatively large tolerance range with regard to the positioning of the printed circuit board relative to the component, the electronic assembly is simple to design and easy to assemble.

Accordingly, a method for assembling an electronic assembly, in particular the electronic assembly described above, is also provided. A housing and a contact-making arrangement are first provided in the method for assembly. This is in particular the contact-making arrangement described above. The next step is to arrange a component in the housing. This is in particular a power component. The joining partner is electrically conductively connected to the component or projects in particular from the component. In the next step, the printed circuit board of the contact-making arrangement described is inserted into the housing with simultaneous attachment of the clamping connector on the joining partner. The printed circuit board is then preferably connected, for example screwed, to the housing.

### BRIEF DESCRIPTION OF THE DRAWINGS

An exemplary embodiment of the invention is described in detail hereinafter with reference to the accompanying drawings. The drawings show:

FIG. 1 a schematic plan view of a contact-making arrangement according to the invention according to one exemplary embodiment,

FIG. 2 a perspective view of the contact-making arrangement according to the invention according to the exemplary embodiment,

FIG. 3 a detail of FIG. 2, and

FIG. 4 a schematic sectional view of an electronic assembly according to the invention with the contact-making arrangement according to the invention according to the exemplary embodiment.

### DETAILED DESCRIPTION

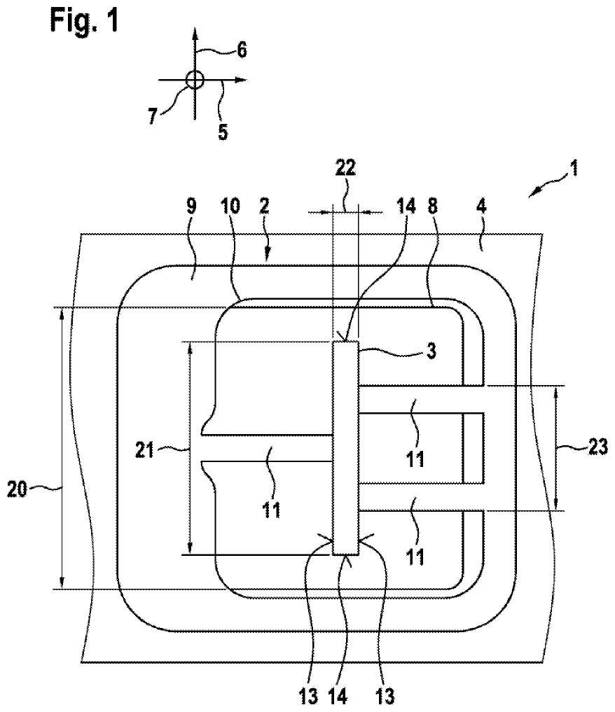

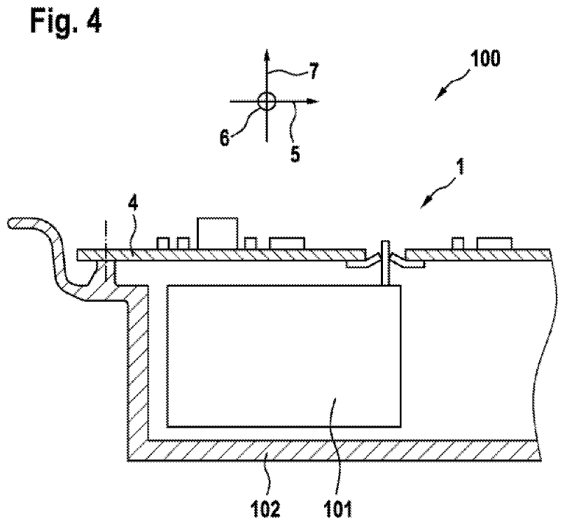

In the following, a contact-making arrangement 1 is explained based on FIGS. 1 to 3, which can be a component of an electronic assembly 100 according to FIG. 4.

According to FIGS. 1 to 3, the contact-making arrangement 1 comprises a clamping connector 2, a joining partner 3, configured as a contact blade, and a printed circuit board 4. The printed circuit board 4 extends in the plane of an x-axis 5 and a y-axis 6. A z-axis 7 is perpendicular to the x-axis 5 and to the y-axis 6.

The printed circuit board 4 comprises a cutout 8, which in the exemplary embodiment shown is configured as a through-hole. The clamping connector 2 is located on this cutout 8.

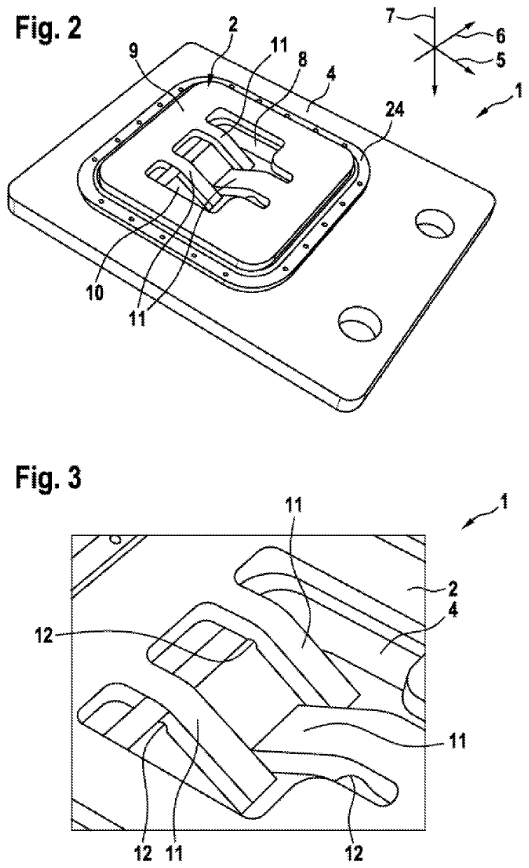

The clamping connector 2 is configured as a one-piece component made of sheet metal. The clamping connector 2 is attached on the printed circuit board 4 as a surface-mounted device (SMD) and is contact-connected. For this purpose, an SMD connection 24 (see FIG. 2) is configured in a closed annular fashion around the clamping connector 2.

The clamping connector 2 comprises a frame 9, which surrounds a hole 10. The hole 10 is aligned with the cutout 8 of the printed circuit board 4. From frame 9, a plurality of flexible contact elements 11 extend over or into the hole 10. In the exemplary embodiment shown, a contact element 11 is provided on one side, with two contact elements 11 opposite it on the other side.

The clamping connector 2 lies flat on the printed circuit board 4. The contact elements 11 extend parallel to the x-axis 5 and are pre-curved in a direction parallel to the z-axis 7. To adjust the spring force of the contact elements 11, each one has a notch 12 (see FIG. 3).

The joining partner 3 configured as a contact blade has two opposing contact surfaces 13. The contact surfaces 13 are perpendicular to the x-axis 5. The contact elements 11 slidably abut these contact surfaces 13.

Furthermore, the joining partner 3 comprises two opposing flank surfaces 14, which in the exemplary embodiment shown are perpendicular to the y-axis 6. Contrary to the schematic representation in FIG. 1, these flank surfaces 14 can also be round, for example. No contact elements 11 abut the flank surfaces 14. This results in a free movement of the joining partner 3 parallel to the y-axis 6 with simultaneous sliding of the contact elements 11 on the two contact surfaces 13.

Even with a movement of the joining partner 3 parallel to the z-axis 7, the contact elements 11 slide on the two contact surfaces 13. When the joining partner 3 moves parallel to the x-axis 5, the contact elements 11 deform as elastically as possible.

FIG. 1 shows a clear width 20 parallel to the y-axis 6 of the hole 10 and the cutout 8. In the exemplary embodiment shown, the hole 10 is somewhat larger than the cutout 8, so that the cutout 8 specifies the clear width 20.

In addition, FIG. 1 shows a distance between the two contact elements 11. The joining partner 3 has a width 22 parallel to the x-axis 5, which is substantially smaller than its length 21 defined parallel to the y-axis 6.

The clear width 20 is designed substantially longer than the length 21 of the joining partner 3, so that the joining partner 3 can be moved as far as possible parallel to the y-axis 6. In particular, the clear width 20 is at least 110% of the length 21.

The length 21 is selected to be as large as possible compared to the distance 23, so that both contact elements 11 remain in contact with the contact surface 13 despite the joining partner 3 being moved parallel to the y-axis 6. In particular, the length 21 is at least 110% of the distance 23.

FIG. 4 shows the electronic assembly 100 in a purely schematic section. The electronic assembly 100 comprises a housing 102 in which a component 101, in particular a power component, is arranged. The joining partner 3 extends from the component 101. In particular, the joining partner 3 is fixedly connected to the component 101. The contact-connection between the joining partner 3 and the clamping connector 2 is made by simply attaching the described printed circuit board 4.

1. A contact-making arrangement (1) for electrically conductive connection between a clamping connector (2) and a joining partner (3), comprising
a printed circuit board (4) with a cutout (8), wherein an x-axis (5) and y-axis (6) perpendicular thereto are defined in a plane of the printed circuit board (4),
a joining partner (3),
and a clamping connector (2) which is arranged on the cutout (8) and has at least one flexible contact element (11), wherein the joining partner (3) can be inserted through the clamping connector (2) and into the cutout (8) with simultaneous contact-connection and deformation of the at least one contact element (11),
wherein the inserted joining partner (3) can be moved parallel to the y-axis (6) in a manner sliding on the at least one contact element (11).

2. The contact-making arrangement according to claim 1, wherein the joining partner (3) is configured as a contact blade.

3. The contact-making arrangement according to claim 1, wherein the inserted joining partner (3) has two opposing contact surfaces (13) and is only contact-connected at these two contact surfaces (13).

4. The contact-making arrangement according to claim 1, wherein the inserted joining partner (3) can be moved parallel to the x-axis (5) with simultaneous deformation of the at least one contact element (11).

5. The contact-making arrangement according to claim 1, wherein the clamping connector (2) comprises a sheet metal plate, which lies flat on the printed circuit board (4).

6. The contact-making assembly of claim 1, wherein the at least one flexible contact element (11) comprises a notch (12).

7. The contact-making arrangement according to claim 1, wherein the clamping connector (2) comprises a frame (9) which surrounds a hole (10) for receiving the joining partner (3), wherein the frame (9) is integral with the at least one contact element (11).

8. The contact-making arrangement according to claim 1, wherein the clamping connector (2) is mounted and contact-connected as a surface-mounted device (SMD) on the printed circuit board (4) by surface mounting.

9. An electronic assembly (100) comprising a housing (102) and at least one component (101) which is arranged in the housing (102) and a contact-making arrangement (1) according to claim 1, wherein the joining partner (3) is electrically conductively connected to the component (101) and wherein the printed circuit board (4) is inserted in the housing (102) and the joining partner (3) is inserted in the clamping connector (2).

10. A method for assembling an electronic assembly (100) comprising the steps of:
providing a housing (102) and a contact-making arrangement (1) according to claim 1,
arranging a component (101) in the housing (102), wherein the joining partner (3) of the contact-making arrangement (1) is electrically conductively connected to the component (101),
and inserting the printed circuit board (4) of the contact-making arrangement (1) into the housing (102) with simultaneous attachment of the clamping connector (2) on the joining partner (3).

11. The method according to claim 10, the joining partner (3) projects out of the component (101).

12. The contact-making arrangement according to claim 5, wherein the sheet metal plate is punched from sheet metal.

13. The electronic assembly (100) according to claim 9, wherein the joining partner (3) projects out of the component (101).
